(19) United States
(12) Patent Application Publication
(10) Pub. No.: US 2009/0153033 A1
(43) Pub. Date: Jun. 18, 2009

(54) ORGANIC LIGHT EMITTING DIODE DEVICE AND METHOD OF MANUFACTURING THE SAME

(76) Inventors: Dong-Won LEE, Seongnam-si (KR); Chang-Woong Chu, Suwon-si (KR); Jin-Koo Chung, Suwon-si (KR)

Correspondence Address: Haynes and Boone, LLP;IP Section, 2323 Victory Avenue, SUITE 700, Dallas, TX, 75219, US

(21) Appl. No.: 12/201,973

(22) Filed: Aug. 29, 2008

(30) Foreign Application Priority Data
Dec. 12, 2007 (KR) 10-2007-0129188

(51) Int. Cl. H01L 51/10; H01L 51/40

(52) U.S. Cl. 313/504; 438/29; 257/E51.018

(57) ABSTRACT

An organic light-emitting diode device and a method of manufacturing the organic light-emitting diode device are disclosed. The organic light-emitting diode device includes a thin film transistor, an anode electrode electrically connected to the thin film transistor, a hole injection layer formed on the anode electrode, an etch-out buffer layer formed on the hole injection layer, the etch-out buffer layer having a first hole that exposes the hole injection layer, a barrier rib formed on the etch-out buffer layer, the barrier rib having a second hole that overlaps the first hole, an organic emission layer formed on a portion of the hole injection layer which is exposed through the first hole and second hole, and a cathode electrode formed on the organic emission layer.

### CROSS-REFERENCE TO RELATED APPLICATION

This application claims priority to and the benefit of Korean Patent Application No. 10-2007-0129188, filed in the Korean Intellectual Property Office on Dec. 12, 2007, the disclosure of which is incorporated herein by reference in its entirety.

### BACKGROUND

1. Technical Field

The present invention generally relates to an organic light-emitting diode device whose organic light emitting layer is evenly formed and a method of manufacturing the organic light-emitting diode device.

2. Description of the Related Art

Generally, organic light-emitting diode (OLED) devices are next generation display devices that have high energy efficiency with reduced power consumption.

OLED devices include a substrate, thin film transistors (TFTs) formed on the substrate, and OLEDs electrically connected to the TFTs. At least one TFT is provided near each pixel to drive the OLED.

The OLED includes an anode electrode, a cathode electrode, and a light-emitting layer disposed between the anode electrode and the cathode electrode. The OLED has a plurality of barrier ribs to form a separate light-emitting layer for each pixel, so that each pixel can be independently driven. Before forming the light-emitting layer, a hole injecting layer may be formed in a space between the barrier ribs.

An interfacial phenomenon occurs when the hole injection layer is formed between the barrier ribs and may cause the hole injection layer to be uneven, so that an emission layer may fail to cover the entire surface of the hole injection layer. This may result in a direct contact between a cathode electrode and the hole injection layer which may cause a failure of light emission and corresponding deterioration in display quality.

### SUMMARY

In accordance with one or more embodiments of the present invention, an organic light-emitting diode device is disclosed that can prevent the direct contact of the hole injection layer and the cathode electrode and acquire even display properties, and can prevent the loss and damage of the hole injection layer during the formation of the barrier rib by forming an inorganic insulating layer on the hole injection layer before the formation of the barrier rib.

In accordance with another of the present invention, a method of manufacturing the organic light-emitting diode device is disclosed.

One embodiment of the present invention provides an organic light-emitting diode device including a thin film transistor, an anode electrode electrically connected to the thin film transistor, a hole injection layer formed on the anode electrode, an etch-out buffer layer formed on the hole injection layer, the etch-out buffer layer having a first hole that exposes the hole injection layer, a barrier rib formed on the etch-out buffer layer, the barrier rib having a second hole that overlaps the first hole, an organic emission layer formed on a portion of the hole injection layer which is exposed through the first hole and second hole, and a cathode electrode formed on the organic emission layer.

The etch-out buffer layer is formed of a non conductive material.

The non conductive material includes at least one of oxide, nitride, and oxynitride.

The etch-out buffer layer has a thickness of about 100 Å to about 20000 Å.

The first hole is undercut near a lower part of the barrier rib.

The second hole is undercut near a lower part of the barrier rib.

The first hole and the second hole are formed to overlap the anode electrode.

The organic emission layer is formed in at least portion of the first hole to prevent the cathode electrode from contacting the hole injection layer.

The organic emission layer is formed by an inkjet method.

The organic light-emitting diode device may further include a hole transportation layer formed between the hole injection layer and the organic emission layer.

The organic emission layer emits at least one of red light, green light, blue light, and white light.

One embodiment of the present invention provides a method of manufacturing an organic light-emitting diode device. The method includes forming an anode electrode on a substrate, the anode electrode electrically connected to a thin film transistor, forming a hole injection layer on the anode electrode, forming an etch-out buffer layer on the hole injection layer, forming a photosensitive organic layer on the etch-out buffer layer, forming a barrier rib by having a first hole pass through the photosensitive organic layer, forming a second hole in the etch-out buffer layer using the barrier rib as a mask, the second hole exposing a portion of the hole injection layer, forming an organic emission layer on the portion of the hole injection layer, and forming a cathode electrode on the organic emission layer.

The etch-out buffer layer is formed of a non conductive material.

The non conductive material includes at least one of oxide, nitride, and oxynitride.

The etch-out buffer layer has a thickness of about 100 Å to about 20000 Å.

The second hole is undercut near a lower part of the barrier rib.

The organic emission layer is formed in at least portion of the second hole.

The organic emission layer is formed by an inkjet method.

Forming the organic emission layer may further include forming a hole transportation layer on the hole injection layer.

Forming the barrier rib may further include performing a hydrophobic treatment on the barrier rib.

### BRIEF DESCRIPTION OF THE DRAWINGS

The above and other features of the present invention will be described in reference to certain embodiments thereof with reference to the attached drawings in which:

FIG. 1 is a plan view illustrating an OLED display according to one embodiment of the present invention;

FIG. 2 is a cross sectional view of the OLED display taken along the line I-I′ of FIG. 1;

FIG. 3 is a cross sectional view illustrating a disconnection of a cathode electrode caused by the increase in thickness of an etch-out buffer layer; and

FIGS. 4A to 4G are cross sectional views illustrating a method of manufacturing an OLED device according to an embodiment of the present invention.

### DETAILED DESCRIPTION

Embodiments of the invention will be described more fully hereinafter with reference to the accompanying drawings, in which various embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

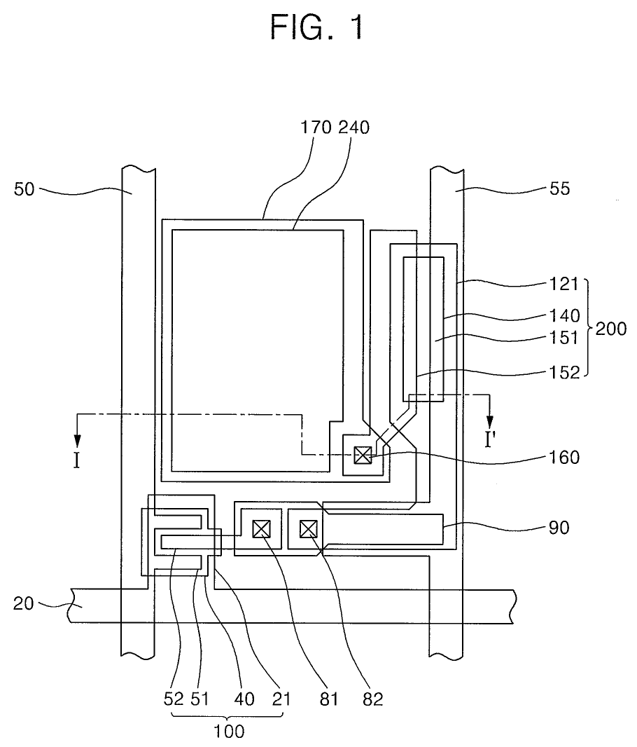

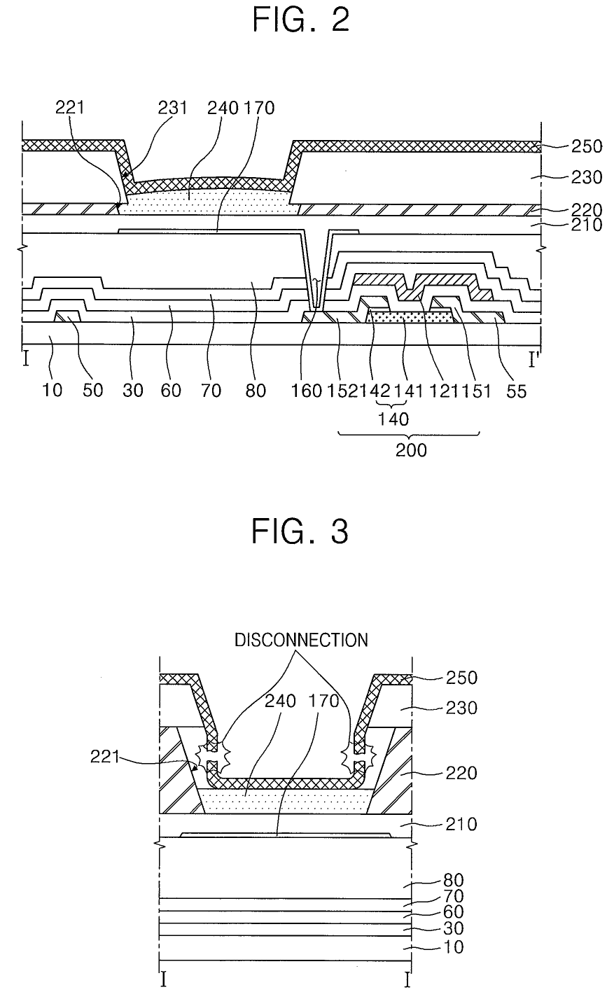

FIG. 1 is a plan view illustrating an OLED device according to one embodiment of the present invention. FIG. 2 is a cross sectional view of the OLED device taken along the line I-I′ of FIG. 1.

Referring to FIGS. 1 and 2, the OLED device includes a substrate 10, first and second thin film transistors (TFTs) 100 and 200, and an OLED. The substrate 10 may be formed of a transparent insulating material, such as glass or plastic.

The first TFT 100 is electrically connected to a gate line 20 and a data line 50, and is turned on when a scan pulse is supplied to the gate line 20, and a data signal is supplied to a data line 50, and the data signal is supplied to a storage capacitor and the second TFT 200. The first TFT 100 includes a first gate electrode 21 electrically connected to the gate line 20, a first source electrode 51 electrically connected to the data line 50, a first drain electrode 52 facing the first source electrode 51, and a first semiconductor pattern 40. The first semiconductor pattern 40 forms a channel between the first source electrode 51 and the first drain electrode 52. The first drain electrode 52 is electrically connected to a second gate electrode 121 of the second TFT 200 and storage capacitor. The first semiconductor pattern 40 may include a first activation layer, and the first activation layer overlaps the first gate electrode 21 with a first insulating layer 30 therebetween, and a first ohmic contact layer formed on the activation layer. The first activation layer and the first ohmic contact layer may be formed of amorphous silicon or polycrystalline silicon.

The second TFT 200 controls the electric current in response to a data signal in order to adjust the amount of emission of the OLED. The electric current is supplied from a power line 55 to the OLED, and the data signal is supplied to the second gate electrode 121. The second TFT 200 may include a second gate electrode 121, a source electrode 151, a second drain electrode 152, and a second semiconductor pattern 140. The second gate electrode 121 is electrically connected to the first drain electrode 52 through a connection electrode 90. The second source electrode 151 is electrically connected to the power line 55. The second drain electrode 152 is electrically connected to the anode electrode 170 of the OLED and faces the second source electrode 151. The second semiconductor pattern 140 forms a channel between the second source electrode 151 and the second drain electrode 152. The connection electrode 90 is formed of the same material as that of the anode electrode 170 on a planarization layer 80. The planarization layer 80 is formed on a protective layer 70 to make the anode electrode 170 level.

The connection electrode 90 electrically connects the first drain electrode 52 of the first TFT 100 to the second gate electrode 121 of the second TFT 200, and the first drain electrode 52 of the first TFT 100 is exposed through a first contact hole 81, and the second gate electrode 121 of the second TFT 200 is exposed through a second contact hole 82. The first contact hole 81 passes through the protective layer 70 and planarization layer 80 to expose the first drain electrode 52. The second contact hole 82 passes through a second gate insulating layer 60, the protective layer 70, and the planarization layer 80 to expose the second gate electrode 121.

The second semiconductor pattern 140 includes a second activation layer 141 and a second ohmic contact layer 142. The second activation layer 141 overlaps the second gate electrode 121 with the first gate insulating layer 30 therebetween. The second ohmic contact layer 142 is formed on the second activation layer 141 except for regions of the channel in order to make an ohmic contact with the second source electrode 151 and second drain electrode 152. The second activation layer 140 may be formed of amorphous silicon or polycrystalline silicon.

The storage capacitor is formed by overlapping the power line 55 with the second gate electrode 121 of the second TFT 200, with the first insulating layer 30 therebetween. A voltage charged to the storage capacitor may allow the second TFT 200 to supply a constant electric current to the OLED until receiving the data signal of a subsequent frame, so that the OLED can maintain light emission, although the first TFT 100 is turned off.

The OLED may include the anode electrode 170 formed on the planarization layer 80, a barrier rib 230, an hole injection layer 210 formed above the anode electrode 170 and the planarization layer 80, an etch-out buffer layer 220 formed between the hole injection layer 210 and barrier rib 230, an organic emission layer 240 formed on the hole injection layer 210, and the cathode electrode 250 formed on the organic emission layer 240.

The anode electrode 170 may be independently formed near each sub pixel on the planarization layer 80. The anode electrode 170 is electrically connected to the second drain electrode 152 of the second TFT 200, and the second drain electrode 152 is exposed through a third contact hole 160 that passes through the first gate insulating layer 30, the second gate insulating layer 60, the protective layer 70, and the planarization layer 80. The anode electrode 170 may be formed of indium tin oxide (ITO), tin oxide (TO), indium zinc oxide (IZO), and indium tin zinc oxide (ITZO).

The cathode electrode 250 is formed on the organic emission layer 240. The cathode electrode 250 may be formed of a metal having a low work function. More specifically, a part of the cathode electrode 250, which is adjacent to the organic emission layer 240, may be formed of a low-work function metal. The cathode electrode 250 may be formed of Ag, Mg, Al, Pt, Pd, Au, Ni, Nd, Ir, Cr, Li, Ca, and a compound thereof which have high electron supplying capability and high reflection properties.

The hole injection layer 210 is formed on the entire substrate to cover the anode electrode 170. The hole injection layer 210 may be formed of a water-soluble high molecular organic material, such as polyethylene dioxy thiophene. Alternatively, the hole injection layer 210 may be formed only on the anode electrode 170.

The etch-out buffer layer 220 is formed on the hole injection layer 210, and includes a first hole 221, wherein the first hole 221 overlaps the anode electrode 170. The etch-out buffer layer 220 may be formed of a non-conductive material. The etch-out buffer layer 220 may be formed of an inorganic insulating material or organic insulating material. The inorganic insulating material may be formed in a single layer of an oxide-based material, a nitride-based material, or an oxynitride-based material, for example, such as SiOx, SiNx, SiOxNy, AlOx, AlNx, AlOxNy, SiCxOy, or in a multi-layer thereof. The organic insulating material may include at least one of a polyimide-based resin, an acrylic-based resin, benzocyclobutene (BCB), and perfluorocyclobutene (PFCB).

The etch-out buffer layer 220 may be formed to have a thickness of about 100 Å to about 20000 Å. A thickness of less than 100 Å may damage the hole injection layer 210 under the etch-out buffer layer 220 when etching is performed to form the first hole 221. A thickness of more than 20,000 Å may lengthen the period of time required for etching of the etch-out buffer layer 220. Additionally, a large thickness of the etch-out buffer layer 220 may cause the cathode electrode 250 to be disconnected as shown in FIG. 3, because the organic emission layer 240 is spaced too far from the barrier rib 230. Accordingly, the etch-out buffer layer 220 may be formed to have a thickness of less than about 20000 Å.

The first hole 221 passes through the etch-out buffer layer 220 to expose the hole injection layer 210. The first hole 221 may be formed to overlap the anode electrode 170. The top surface of the first hole 221 may have a smaller area than that of a second hole 231. The periphery of the first hole 221 may be covered by the barrier rib 230 whose lower part is intruded into the first hole 221.

The organic emission layer 240 is formed in the first hole 221 to cover the exposed hole injection layer 210. Accordingly, the cathode electrode 250 may be prevented from directly accessing the hole injection layer 210.

The barrier rib 230, which includes the second hole 231 overlapping the first hole 221 is formed on the etch-out buffer layer 220. The barrier rib 230 is formed of a photosensitive organic insulating material. The second hole 231 is formed to overlap the first hole 221 and the anode electrode 170 so that the organic emission layer 240 can be easily provided in the first hole 221.

The area of the bottom surface of the second hole 231 may be smaller than that of the top surface. A hydrophobic treatment is performed on the barrier rib 230 so that the liquid material for the organic emission layer 240 may be flowed in the first hole 221 along the inner surface of the second hole 231 at the time of the formation of the organic emission layer 240.

The organic emission layer 240 may be formed of a high molecular material, such as polyphenylenevinylene (PPV)-based material and polyfluorene-based material.

The organic emission layer 240 may also be formed of a low molecular material, such as copper phthalocyanine (CuPc) and tris-8-hydroxyquinoline aluminum (Alq3).

The OLED may further include a hole transportation layer that serves as a buffer between the organic emission layer 240 and the hole injection layer 210.

Also, the OLED may further include an electron supply layer and an electron transportation layer between the cathode electrode 250 and the organic emission layer 240. The electron supply layer may be stacked to access the cathode electrode 250, and the electron transportation layer may be stacked between the electron supply layer and the organic emission layer 240.

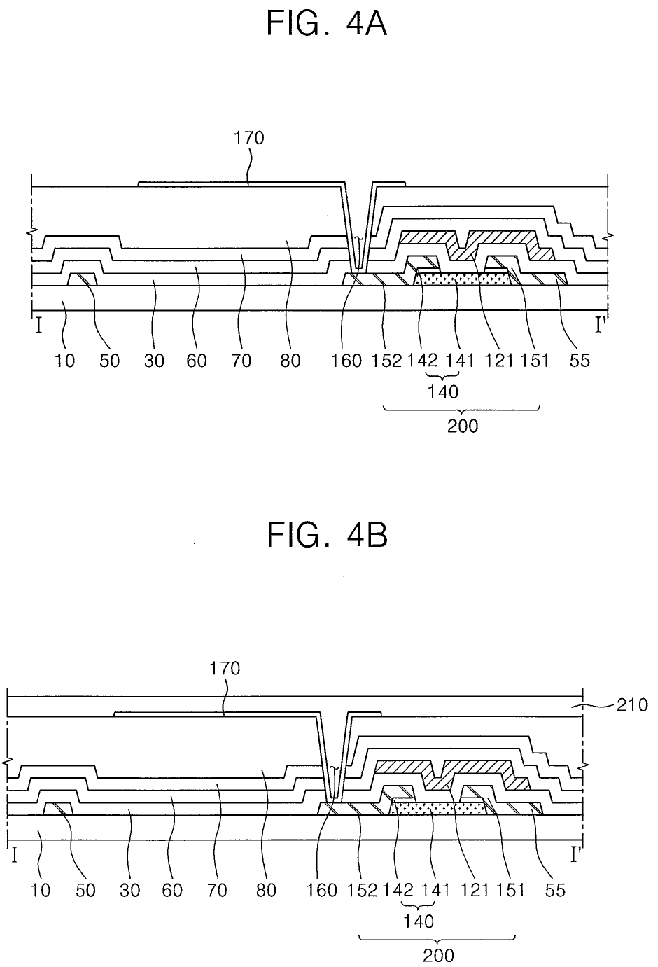

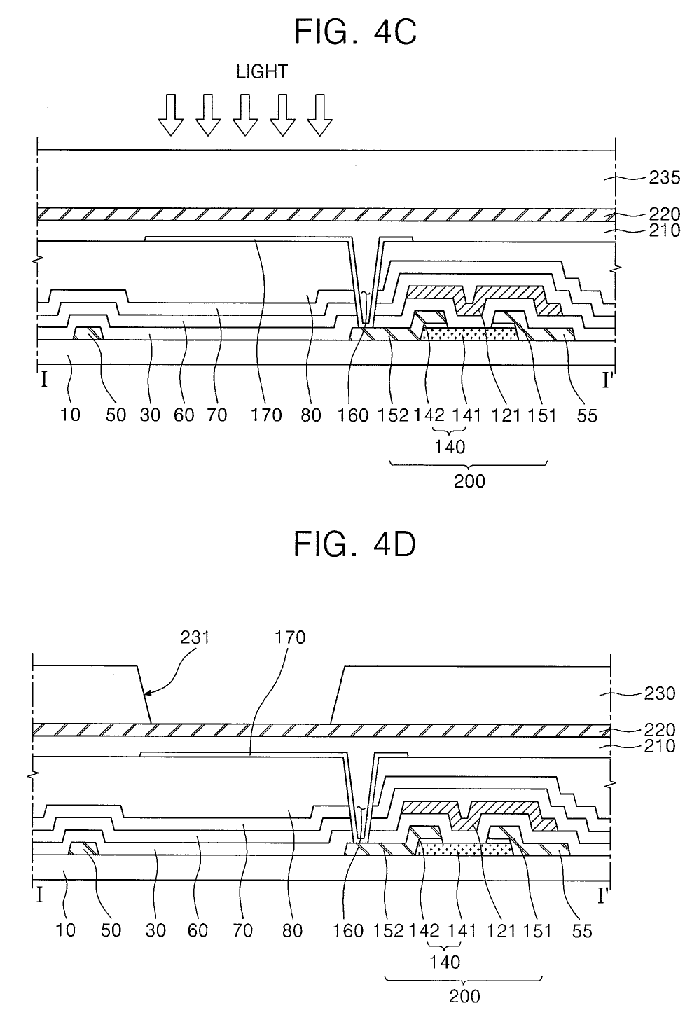

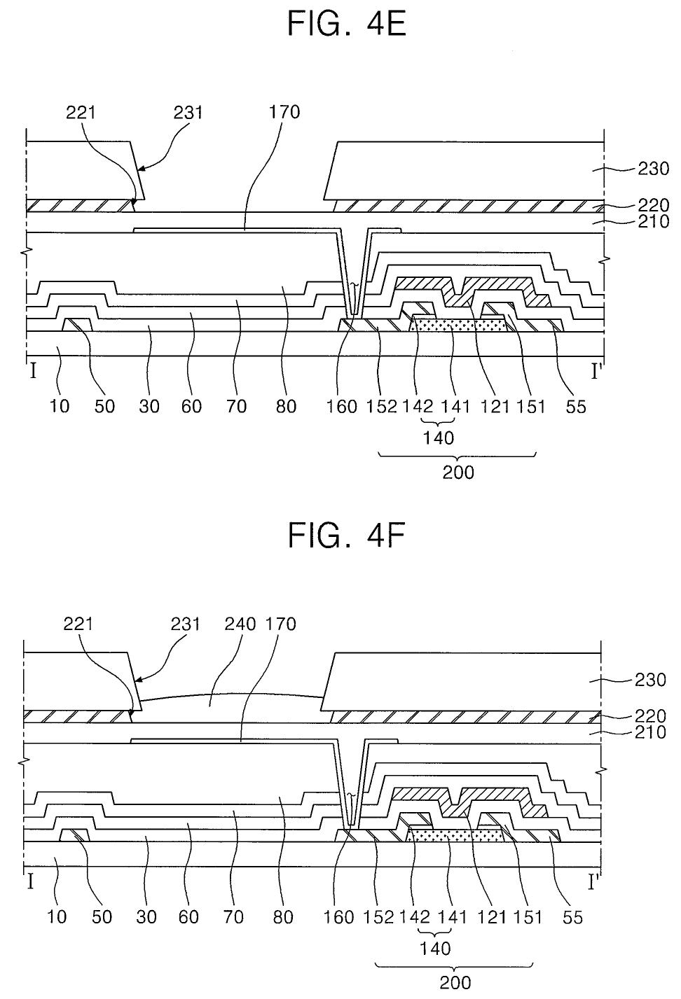

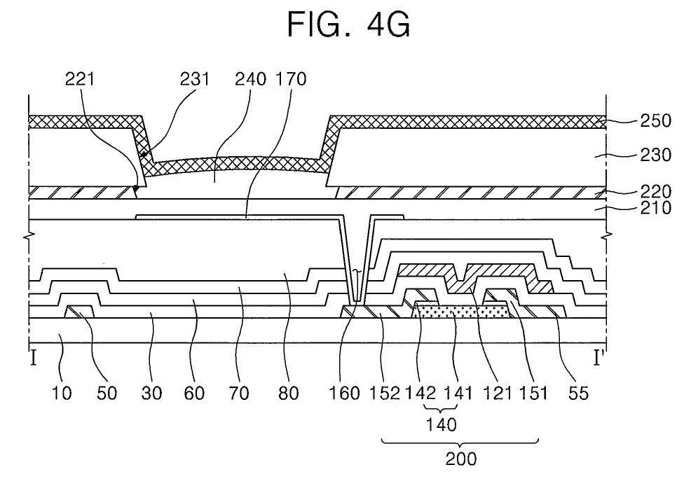

FIGS. 4A to 4G are cross-sectional views illustrating a method of manufacturing an OLED device according to an embodiment of the present invention.

Referring to FIGS. 1 and 4A, the second TFT 200 is formed on the substrate 10. The first TFT 100, the data line 50, the power line 55, and the gate line 20 may be formed along with the second TFT 200.

More specifically, first, the second semiconductor pattern 140 of the second TFT 200 is formed on the substrate 10. The second semiconductor pattern 140 may be formed of amorphous silicon or polycrystalline silicon. The second semiconductor pattern 140 may include the second activation layer 141 and the second ohmic contact layer 142.

Next, the second source electrode 151 and the second drain electrode 152 are formed. More specifically, a conductive metal layer is deposited on the entire top surface of the substrate 10 using a sputtering method, and then is patterned to form the second source electrode 151 and the second drain electrode 152. During forming the second source electrode 151, the power line 55 and data line 50 may be also formed.

Then, the first gate insulating layer 30 is formed on the entire substrate 10 using an inorganic insulating material such as SiOx and SiNx. Subsequently, the first gate electrode 21 and the second gate electrode 121 are simultaneously formed on the first gate insulating layer 30. At this time, the gate line 20 electrically connected to the first gate electrode 21 may be formed together. Next, the second gate insulating layer 60 is formed on the substrate 10 using the same material and manner as those of the first gate insulating layer 30. The first gate electrode 21 and the second gate electrode 121 are formed on the substrate 10. Then, the first semiconductor pattern 40 is formed on the second gate insulating layer 60 to overlap the first gate electrode 21. The first semiconductor pattern 40 may be formed of amorphous silicon or polycrystalline silicon. Next, the first source electrode 51 and the first drain electrode 52 are formed. Subsequently, the protective layer 70 is formed on the substrate 10 having the first and second source electrodes 51 and 151 and the first and second drain electrodes 52 and 152 are formed. The planarization layer 80 may be further formed on the protective layer 70. The protective layer 70 may be formed of an inorganic insulating material such as SiNx and SiOx. Then, the planarization layer 80 which includes the first to third contact holes 81, 82, and 160 is formed on the substrate 10, on which the protective layer 70 has been formed, using, for example, spin coating or spinless coating.

The first to third contact holes 81, 82, and 160 are formed by patterning the first and second gate insulating layers 30 and 60, the protective layer 70, and the planarization layer 80 using photolithography and etching.

Next, the anode electrode 170 is formed on the planarization layer 80. More specifically, a transparent conductive layer is formed on the planarization layer 80 using a deposition method such as sputtering, and then patterned using photolithography and etching to form the anode electrode 170. The transparent conductive layer may be formed of a high-work function conductive material such as ITO, TO, IZO, and ITZO. The connection electrode 90 may be further provided.

Subsequently, the hole injection layer 210 is formed on the anode electrode 170 and the planarization layer 80.

The hole injection layer 210 may be formed, for example, by coating an organic material, such as polyethylene dioxy thiophene, on the entire surface of the anode electrode 170 and the planarization layer 80. The entire surface coating as above beneficially reduces the number of inkjet process steps, thereby reducing the probability of deterioration in display quality caused during the inkjet process.

Then, the etch-out buffer layer 220 and a photosensitive organic layer 235 are formed on the hole injection layer 210 as shown in FIGS. 4C and 4D.

The etch-out buffer layer 220 may be formed of at least one of inorganic insulating materials, such as SiOx, SiNx, SiOxNy, AlOx, AlNx, AlOxNy, and SiCxOy, or at least one of organic insulating materials, such as a polyimide-based resin, an acrylic-based resin, benzocyclobutene (BCB), and perfluorocyclobutene (PFCB), using a deposition method such as CVD, PECVD, and spin or spinless coating. The etch-out buffer layer 220 may be formed to have a thickness of about 200 Å to about 20000 Å. Next, the photosensitive organic layer 235 is formed using spin coating or spinless coating. The photosensitive organic layer 235 may be formed of a positive photosensitive material. Subsequently, the photosensitive organic layer 235 is irradiated, with a mask disposed thereon, and then is developed to form the second hole 231. Light is illuminated only to the region where the second hole 231 is to be formed.

The second hole 231 is formed to overlap the anode electrode 170. Accordingly, the barrier ribs 230 may be formed in which the second hole 231 is provided. The etch-out buffer layer 220, which is arranged under the barrier rib 230, may prevent the damage to the hole injection layer 210 at the time of the formation of the second hole 231. The etch-out buffer layer 220 covering the entire top surface of the hole injection layer 210 may prevent the loss of the hole injection layer 210 during the surface treatment of the barrier rib 230.

Next, the barrier rib 230 undergoes a surface treatment to have a hydrophobic properties. The surface treatment is performed using fluoro-based plasma. The fluoro-based plasma is made of a fluoro-based gas such as CF₄ and C₃F₈. The hydrophobic surface treatment allows the liquid material for the organic emission layer to be easily flowed into the second hole 231 despite its misalignment during the inkjet process.

Next, the first hole 221 is formed on the etch-out buffer layer 220 using the barrier rib 230 as a mask, as shown in FIG. 4E. The hole injection layer 210 is exposed by the first hole 221. The first hole 221 is formed through a wet etching method. In this case, the first hole 221 may be over etched to make the first hole have a constant size at each pixel region.

The area of the bottom surface of the first hole 221 may be smaller than that of the top surface. The first hole 221 may undercut the second hole 231. At least part of the upper half of the first hole 221 may undercut the second hole 231 to be covered by the lower half of the second hole 231. The first hole 221 is formed to overlap the anode electrode 170.

Next, the organic emission layer 240 is formed on a portion of the hole injection layer 210, which is exposed through the first and second holes 221 and 231, using an inkjet method. A liquid material for the organic emission layer 240 may be filled in the first hole 221. Accordingly, the organic emission layer 240 is formed to cover the top surface of the hole injection layer 210, and the top surface of the hole injection layer 210 is exposed by the first and second holes 221 and 231.

The organic emission layer 240 may be formed of organic emission materials which emit red light, green light, and blue light. Also, the organic emission layer 240 may be formed of an organic emission material that emits white light. The organic emission layer 240 may further include an hole transportation layer, an electron injection layer, and an electron transportation layer.

Next, the cathode electrode 250 is formed on the organic emission layer 240 and barrier rib 230 as shown in FIG. 4G. More specifically, the cathode electrode 250 is formed to cover the organic emission layer 240 and barrier ribs 230 using a deposition method such as sputtering. The cathode electrode 250 may be formed of Ag, Mg, Al, Pt, Pd, Au, Ni, Nd, Ir, Cr, Li, Ca, and compounds thereof which have high electron supplying capability and high reflection properties.

The cathode electrode 250 does not contact the hole injection layer 210 since the organic emission layer 240 is formed in the first hole 221 to cover the hole injection layer 210. The etch-out buffer layer 220 being less than 20000 Å in thickness may prevent the open circuit in the cathode electrode 250 even though the organic emission layer 240 is formed thin.

Although the present invention has been described with reference to certain embodiments thereof, it will be understood by those skilled in the art that a variety of modifications and variations may be made to the present invention without departing from the spirit or scope of the present invention defined in the appended claims, and their equivalents.

What is claimed is:

1. An organic light-emitting diode device comprising:
a thin film transistor;
an anode electrode electrically connected to the thin film transistor;
a hole injection layer formed on the anode electrode;
an etch-out buffer layer formed on the hole injection layer, the etch-out buffer layer having a first hole that exposes the hole injection layer;
a barrier rib formed on the etch-out buffer layer, the barrier rib having a second hole that overlaps the first hole;
an organic emission layer formed on a portion of the hole injection layer which is exposed through the first hole and second hole; and
a cathode electrode formed on the organic emission layer.

2. The organic light-emitting diode device of claim 1, wherein the etch-out buffer layer comprises a non conductive material.

3. The organic light-emitting diode device of claim 2, wherein the non conductive material comprises at least one of oxide, nitride, and oxynitride.

4. The organic light-emitting diode device of claim 3, wherein the etch-out buffer layer has a thickness of about 100 Å to about 20000 Å.

5. The organic light-emitting diode device of claim 4, wherein the first hole is undercut near a lower part of the barrier rib.

6. The organic light-emitting diode device of claim 1, wherein the first hole is undercut near a lower part of the barrier rib.

7. The organic light-emitting diode device of claim 6, wherein the first hole and the second hole are formed to overlap the anode electrode.

8. The organic light-emitting diode device of claim 7, wherein the organic emission layer is formed in at least portion of the first hole to prevent the cathode electrode from contacting the hole injection layer.

9. The organic light-emitting diode device of claim 1, wherein the organic emission layer is formed by an inkjet method.

10. The organic light-emitting diode device of claim 9, further comprising:
a hole transportation layer formed between the hole injection layer and the organic emission layer.

11. The organic light-emitting diode device of claim 10, wherein the organic emission layer emits at least one of red light, green light, blue light, and white light.

12. A method of manufacturing an organic light-emitting diode device comprising:
forming an anode electrode on a substrate, the anode electrode electrically connected to a thin film transistor;
forming a hole injection layer on the anode electrode;
forming an etch-out buffer layer on the hole injection layer;
forming a photosensitive organic layer on the etch-out buffer layer;
forming a barrier rib by having a first hole pass through the photosensitive organic layer;
forming a second hole in the etch-out buffer layer using the barrier rib as a mask, the second hole exposing a portion of the hole injection layer;
forming an organic emission layer on the portion of the hole injection layer; and
forming a cathode electrode on the organic emission layer.

13. The method of claim 12, wherein the etch-out buffer layer comprises a non conductive material.

14. The method of claim 13, wherein the non conductive material comprises at least one of oxide, nitride, and oxynitride.

15. The method of claim 14, wherein the etch-out buffer layer has a thickness of about 100 Å to about 20,000 Å.

16. The method of claim 12, wherein the second hole is undercut near a lower part of the barrier rib.

17. The method of claim 16, wherein the organic emission layer is formed in at least portion of the second hole.

18. The method of claim 17, wherein the organic emission layer is formed by an inkjet method.

19. The method of claim 18, wherein said forming the organic emission layer further comprises forming a hole transportation layer on the hole injection layer.

20. The method of claim 12, wherein said forming the barrier rib further comprises performing a hydrophobic treatment on the barrier rib.
